(19) United States
(12) Patent Application Publication
(10) Pub. No.: US 2024/0356134 A1
(43) Pub. Date: Oct. 24, 2024

(54) BATTERY PACK

(71) Applicant: TOYOTA JIDOSHA KABUSHIKI KAISHA, Toyota-shi (JP)

(72) Inventors: Mitsutoshi OTAKI, Susono-shi (JP); Shinji NAKANISHI, Mishima-shi (JP); Tetsuya WASEDA, Susono-shi (JP); Jun YOSHIDA, Mishima-shi (JP); Tsubasa MIGITA, Sakai-shi (JP); Yoshihiro UCHIDA, Nagakute-shi (JP)

(73) Assignee: TOYOTA JIDOSHA KABUSHIKI KAISHA, Toyota-shi (JP)

(21) Appl. No.: 18/433,583

(22) Filed: Feb. 6, 2024

(30) Foreign Application Priority Data
Apr. 18, 2023 (JP) 2023-067579

(51) Int. Cl. H01M 50/242; H01M 10/48; H01M 50/209

(52) U.S. Cl. CPC H01M 50/242; H01M 10/482; H01M 50/209

(57) ABSTRACT

The control device executes a process including a step of acquiring a detected value from each surface pressure sensor when charging is in progress, a step of specifying a corresponding partial pressurizing unit when it is determined that there is a reaction uneven portion, a step of outputting a pressurization command, a step of determining whether or not pressurization is completed, and a step of outputting a pressurization release command when it is determined that pressurization is completed.

### CROSS-REFERENCE TO RELATED APPLICATION

This application claims priority to Japanese Patent Application No. 2023-067579 filed on Apr. 18, 2023, incorporated herein by reference in its entirety.

### BACKGROUND

### 1. Technical Field

The present disclosure relates to a configuration of a battery pack.

### 2. Description of Related Art

For example, an all-solid-state battery that is fully solidified by using a solid electrolyte is known as a secondary battery. In the all-solid-state battery, adhesion between a cathode layer, a solid electrolyte layer, and an anode layer that are constituent members affects various characteristics of the battery. Therefore, there is a demand for a technology for appropriately detecting reaction unevenness caused by the adhesion.

Japanese Unexamined Patent Application Publication No. 2020-161300 (JP 2020-161300 A) discloses a technology for estimating a distribution state of lithium in an anode active material layer by using an estimation model.

### SUMMARY

However, the reaction unevenness in the all-solid-state battery varies in a plane, and it is therefore required to appropriately detect the position of the reaction unevenness in the plane. In JP 2020-161300 A, the reaction unevenness in the plane is not taken into consideration. Therefore, it is not possible to appropriately detect the position of the reaction unevenness in the plane.

The present disclosure has been made to solve the above problem. An object of the present disclosure is to provide a battery pack that appropriately detects reaction unevenness in an all-solid-state battery.

A battery pack according to an aspect of the present disclosure includes: a first all-solid-state battery; a second all-solid-state battery; a surface pressure sensor provided between the first all-solid-state battery and the second all-solid-state battery in a bound state and configured to detect a distribution of an in-plane pressure between the first all-solid-state battery and the second all-solid-state battery; and a control device configured to detect, by using a detection result from the surface pressure sensor, a portion where a local pressure increase occurs between the first all-solid-state battery and the second all-solid-state battery as a portion where reaction unevenness occurs.

With this configuration, the distribution of the in-plane pressure between the first all-solid-state battery and the second all-solid-state battery is detected by using the surface pressure sensor. Therefore, the portion where the reaction unevenness occurs can be detected with high accuracy by detecting the portion where the local pressure increase occurs.

In the above aspect, the first all-solid-state battery and the second all-solid-state battery may have a characteristic that a thickness in an arrangement direction of the first all-solid-state battery and the second all-solid-state battery increases compared with a thickness in an initial state due to the reaction unevenness that occurs during charging or discharging of the battery pack.

With this configuration, the portion where the reaction unevenness occurs can be detected with high accuracy by detecting, with the surface pressure sensor, the portion where the local pressure increase occurs.

In the above aspect, the surface pressure sensor may be configured to detect the distribution of the in-plane pressure between the first all-solid-state battery and the second all-solid-state battery on an end side close to a first terminal of the first all-solid-state battery and a second terminal of the second all-solid-state battery in a plane.

With this configuration, the distribution of the in-plane pressure on the end side close to the first terminal and the second terminal where the reaction unevenness is likely to occur is detected. Further, the portion where the reaction unevenness occurs can be detected with high accuracy while suppressing an increase in cost.

According to the present disclosure, it is possible to provide the battery pack that appropriately detects the reaction unevenness in the all-solid-state battery.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a diagram illustrating an example of a configuration of a battery pack;

FIG. 2 is a diagram illustrating an example of a configuration of an all-solid-state battery;

FIG. 3 is a diagram illustrating an example of the configuration of the first pressurizing unit and the second pressurizing unit;

FIG. 4 is a flowchart illustrating an example of processing executed in the control device;

FIG. 5 is a diagram illustrating an example of a configuration of a second pressurizing unit according to a modification;

FIG. 6 is a diagram illustrating an example of a configuration of a surface pressure sensor according to a modification; and

FIG. 7 is a diagram illustrating an example of a configuration of a battery pack according to a modification.

### DETAILED DESCRIPTION OF EMBODIMENTS

Hereinafter, embodiments of the present disclosure will be described in detail with reference to the drawings. In the drawings, the same or corresponding parts are denoted by the same reference numerals. The description will not be repeated.

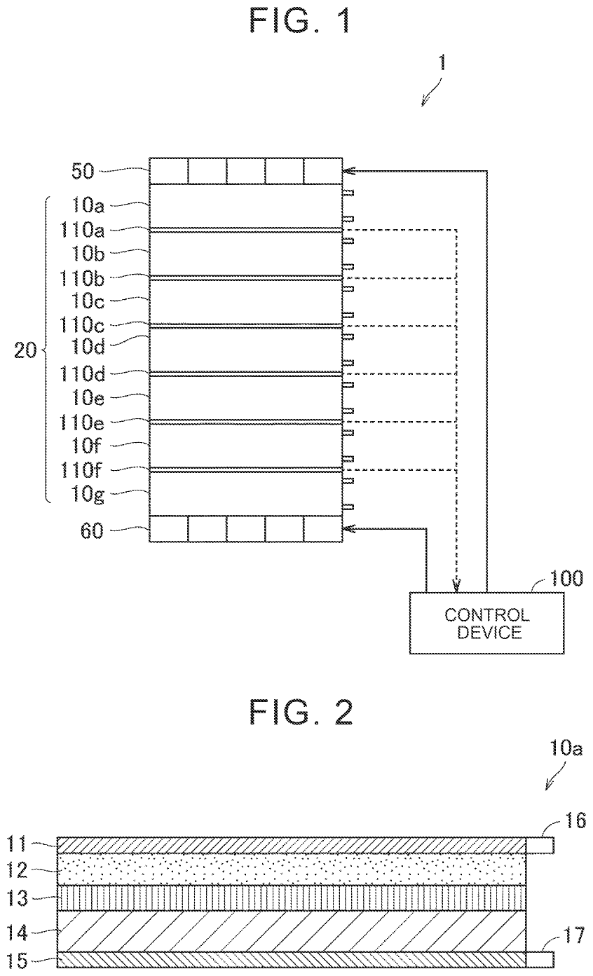

FIG. 1 is a diagram illustrating an example of a configuration of a battery pack 1. For example, the battery pack 1 is mounted on an electrified vehicle such as a battery electric vehicle, plug-in hybrid electric vehicle or another electric moving object. The battery pack 1 shown in FIG. 1 may be charged in a state of being mounted on a vehicle, for example. Alternatively, the battery pack 1 shown in FIG. 1 may be charged in a state of being removed from the vehicle.

As illustrated in FIG. 1, the battery pack 1 includes a stack 20, a first pressurizing unit 50, a second pressurizing unit 60, and a control device 100.

The stack 20 includes a plurality of all-solid-state batteries 10a, 10b, 10c, 10d, 10c, 10f, 10g and a plurality of surface pressure sensors 110a, 110b, 110c, 110d, 110c, 110f (hereinafter, referred to as 110f from the surface pressure sensor 110a). Hereinafter, the plurality of all-solid-state batteries 10a, 10b, 10c, 10d, 10c, 10f, 10g are described as 10g from the all-solid-state battery 10a. Hereinafter, the plurality of surface pressure sensors 110a, 110b, 110c, 110d, 110e, 110f is referred to as the surface pressure sensors 110a to 110f.

10g from the all-solid-state battery 10a is a battery configured by setting a solid electrolyte as an electrolyte, thereby solidifying all of the constituent members. Each of the all-solid-state batteries 10a to 10g has a rectangular shape. Each of the all-solid-state batteries 10a to 10g is stacked in the vertical direction on the paper surface of FIG. 1 with the positive electrode terminal and the negative electrode terminal protruding from the surface on the right side of the paper surface of FIG. 1. In the present embodiment, the stack 20 is described as being composed of seven all-solid-state batteries 10a to 10g. However, the number is not limited to seven.

Further, although not particularly illustrated, each positive electrode terminal and each negative electrode terminal of 10g from the all-solid-state battery 10a are connected to neighboring all-solid-state batteries in a predetermined manner. 10g from the all-solid-state battery 10a may be connected in series, for example. 10g from the all-solid-state battery 10a may include a group of batteries that are partially connected in parallel.

The surface pressure sensor 110a has a sheet-like shape that covers a contact surface with the all-solid-state battery 10a. The surface pressure sensor 110a is provided between the all-solid-state batteries 10a, 10b. The surface pressure sensor 110a detects an in-plane pressure (hereinafter, referred to as an in-plane pressure or a surface pressure) between the all-solid-state batteries 10a, 10b.

The surface pressure sensor 110a includes detection points of a plurality of surface pressures, and transmits detection results of the surface pressures at the detection points to the control device 100. For example, the control device 100 acquires, from the surface pressure sensor 110a, information obtained by combining the coordinates (detection positions) of the detection points and the detection values of the surface pressure. The surface pressure sensors 110b to 110f are provided between the all-solid-state batteries 10b, 10c, the all-solid-state batteries 10c, 10d, the all-solid-state batteries 10d, 10e, the all-solid-state batteries 10c, 10f, and the all-solid-state batteries 10f, 10g. The operation of the surface pressure sensors 110b to 110f is the same as that of the surface pressure sensor 110a. Therefore, the detailed description thereof will not be repeated.

The first pressurizing unit 50 and the second pressurizing unit 60 are provided so as to sandwich the stack 20 from the vertical direction of the paper surface in FIG. 1.

The first pressurizing unit 50 applies a restraining pressure in the downward direction of the plane of FIG. 1. For example, the first pressurizing unit 50 is fixed at a position shown in FIG. 1. The first pressurizing unit 50 is configured to have a member that can expand and contract in the downward direction of the drawing surface of FIG. 1, and thereby exerts a restraining pressure on the stack 20.

The second pressurizing unit 60 applies a restraining pressure in the upward direction of the plane of FIG. 1. The second pressurizing unit 60 is fixed at a position shown in FIG. 1, for example. The second pressurizing unit 60 is configured to have a member that can expand and contract in the upward direction of the plane of FIG. 1, and thereby exerts a restraining pressure on the stack 20. The first pressurizing unit 50 and the second pressurizing unit 60 constitute a “restraining unit” that applies a restraining pressure to the stack 20 in the stacking direction. The positions of the first pressurizing unit 50 and the second pressurizing unit 60 are fixed such that a constant restraining pressure acts on the stack 20 in a non-operating state.

The first pressurizing unit 50 and the second pressurizing unit 60 operate in accordance with a control signal from the control device 100. The first pressurizing unit 50 and the second pressurizing unit 60 operate in accordance with a control signal from the control device 100. Detailed configurations of the first pressurizing unit 50 and the second pressurizing unit 60 will be described later.

The control device 100 includes Central Processing Unit (CPU) and memories. The memory includes various memories such as Read Only Memory (ROM) and Random Access Memory (RAM). The control device 100 controls the first pressurizing unit 50 and the second pressurizing unit 60 to be in a desired condition on the basis of a signal received from each of the surface pressure sensors 110a to 110f and information stored in the memory. The information stored in the memory is, for example, a map and a program. For example, the control device 100 may increase the restraint pressure or reduce the restraint pressure by the first pressurizing unit 50 and the second pressurizing unit 60 based on the detected 110f from the surface pressure sensor 110a when the battery pack 1 is charged.

FIG. 2 is a diagram illustrating an exemplary configuration of an all-solid-state battery 10a. The all-solid-state battery 10a includes a positive electrode current collector 11, a positive electrode layer 12, a solid electrolyte layer 13, a negative electrode layer 14, a negative electrode current collector 15, a positive electrode terminal 16, and a negative electrode terminal 17. Each of the all-solid-state batteries 10b to 10f has the same configuration as that of the all-solid-state battery 10a. Therefore, the detailed description thereof will not be repeated.

The solid electrolyte material included in the solid electrolyte layer 13 is not particularly limited as long as it can be used as a solid electrolyte of an all-solid-state battery. The solid electrolyte material may be, for example, a sulfide-based amorphous solid electrolyte, an oxide-based amorphous solid electrolyte, or the like.

Further, the active material included in the positive electrode layer 12 and the negative electrode layer 14 may be any material that can be used as an electrode active material of an all-solid-state battery. The active material included in the positive electrode layer 12 and the negative electrode layer 14 is not particularly limited. The active material may be, for example, a material such as nickel-cobalt-manganate (NCM), nickel-cobalt-aluminum-lithium (NCA), lithium cobaltate (LCO), (lithium titanate) LTO, and lithium manganate (LMO). Preferably, it is desirable to have a characteristic that the thickness of the all-solid-state battery including the positive electrode layer 12 and the negative electrode layer 14 increases at a position where reaction unevenness occurs during charging or discharging of the battery pack 1.

The positive electrode layer 12 and the negative electrode layer 14 may include conductive auxiliary particles. As the conductive auxiliary material particles, for example, graphite, carbon black, or the like can be used.

The material of the positive electrode current collector 11 and the negative electrode current collector 15 is not particularly limited as long as it has conductivity and functions as a positive electrode current collector and a negative electrode current collector, respectively. Examples of the positive electrode current collector 11 and the negative electrode current collector 15 include Steel Use Stainless (SUS), aluminum, copper, nickel, iron, titanium, and carbon. Further, the shapes of the positive electrode current collector 11 and the negative electrode current collector 15 may be, for example, a foil shape, a plate shape, a mesh shape, or the like. The positive electrode terminal 16 is connected to the positive electrode current collector 11. The negative electrode terminal 17 is connected to the negative electrode current collector 15.

As a battery case (not shown) that encloses each of the all-solid-state batteries 10a to 10g, a known laminate film or the like that can be used in the all-solid-state battery can be used. Examples of such a laminate film include a resin laminate film and a film obtained by depositing metal on a resin laminate film.

As shown in FIG. 1, each of the all-solid-state batteries 10a to 10g has a rectangular shape (square shape). However, each of the all-solid-state batteries 10a to 10g may have a configuration in which a restraining pressure can act on the stack 20 formed by stacking 10g from the all-solid-state battery 10a. Each of the all-solid-state batteries 10a to 10g may have a desired shape, such as a cylindrical shape, a button-type shape, a coin-type shape, or a flat shape, in addition to a square shape.

In 10g from the all-solid-state battery 10a included in the battery pack 1 having the above-described configuration, the adhesion between the positive electrode layer 12, the solid electrolyte layer 13, and the negative electrode layer 14 affects various properties of the battery. Therefore, the reaction unevenness caused by the adhesion in the all-solid-state battery is caused to vary in the plane. Therefore, it is required to appropriately detect the position of the in-plane reaction unevenness.

Therefore, in the present embodiment, it is assumed that a surface pressure sensor and a control device are provided. The surface pressure sensor detects a distribution of the in-plane pressure between the first all-solid-state battery and the second all-solid-state battery in the constrained state. The control device uses the detection result from the surface pressure sensor to detect a portion where a local pressure increase occurs between the first all-solid-state battery and the second all-solid-state battery as a portion where reaction unevenness occurs.

In this way, by using 110f from the surface pressure sensor 110a, the distribution of the in-plane pressure between the all-solid-state batteries 10a and 10f is detected. Therefore, by detecting a portion where a local pressure increase occurs, it is possible to accurately detect a portion where reaction unevenness occurs.

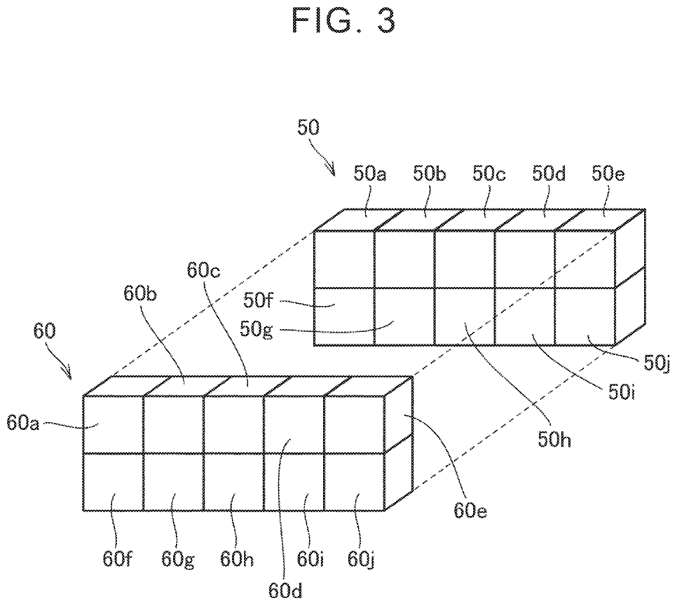

Hereinafter, specific configurations of the first pressurizing unit 50 and the second pressurizing unit 60 will be described with reference to FIG. 3. FIG. 3 is a diagram illustrating an example of the configuration of the first pressurizing unit 50 and the second pressurizing unit 60. In FIG. 3, for convenience of explanation, the display of the stack 20 of the battery pack 1 is omitted. For convenience of explanation, only the first pressurizing unit 50 and the second pressurizing unit 60 are displayed in FIG. 3.

The first pressurizing unit 50 includes first partial pressurizing units 50a, 50b, 50c, 50d, 50c, 50f, 50g, 50h, 50i, 50j (hereinafter, referred to as the first partial pressurizing units 50a to 50j). Each of the first partial pressurizing units 50a to 50j has a contact surface that is rectangular with respect to one surface of the stack 20 in the stacking direction. Each of the first partial pressurizing units 50a to 50j is provided with an actuator (not shown) that is driven in response to a control signal from the control device 100. The actuator of at least one of the first partial pressurizing units 50a to 50j is driven to push the contacting surface with the stack 20, thereby partially increasing the restraining pressure.

The second pressurizing unit 60 includes second partial pressurizing units 60a, 60b, 60c, 60d, 60c, 60f, 60g, 60h, 60i, 60j (hereinafter, referred to as the second partial pressurizing units 60a to 60j). 60j from the second partial pressurizing unit 60a is provided at a position facing 50j from the first partial pressurizing unit 50a in the stacking direction. Each of the second partial pressurizing units 60a to 60j has a contact surface that is rectangular with respect to the other surface of the stack 20 in the stacking direction. Each of the second partial pressurizing units 60a to 60j is provided with an actuator (not shown) that is driven in response to a control signal from the control device 100. The actuator of at least one of the second partial pressurizing units 60a to 60j is driven to push the contacting surface with the stack 20, thereby partially increasing the restraining pressure.

For example, when the first partial pressurizing unit 50a is selected as the control target, the control device 100 selects the second partial pressurizing unit 60a as the control target. As described above, the control device 100 selects, for example, 50j from the first partial pressurizing unit 50a and 60j from the second partial pressurizing unit 60a in association with each other as the control target.

The control device 100 uses the first partial pressurizing unit 50a and the second partial pressurizing unit 60a, for example, when selecting the first partial pressurizing unit 50a and the second partial pressurizing unit 60a as control targets. Control device 100, for example, by using the first partial pressurizing unit 50a and the second partial pressurizing unit 60a, so as to sandwich the contact surface between the contact surface and the second partial pressurizing unit 60a and the stack 20 of the first partial pressurizing unit 50a and the stack 20 to apply a partial restraining pressure to the stack 20.

The same applies to the control device 100 in which 50j and 60j are controlled from the first partial pressurizing unit 50b and the second partial pressurizing unit 60b, respectively. Therefore, the detailed description thereof will not be repeated.

Either of 50j from the first partial pressurizing unit 50a operates to push the stack 20, and the corresponding second partial pressurizing unit of 60j from the second partial pressurizing unit 60a operates to push the stack 20, whereby the restraining pressure is partially increased between the contact surface of the first partial pressurizing unit and the contact surface of the second partial pressurizing unit of the stack 20.

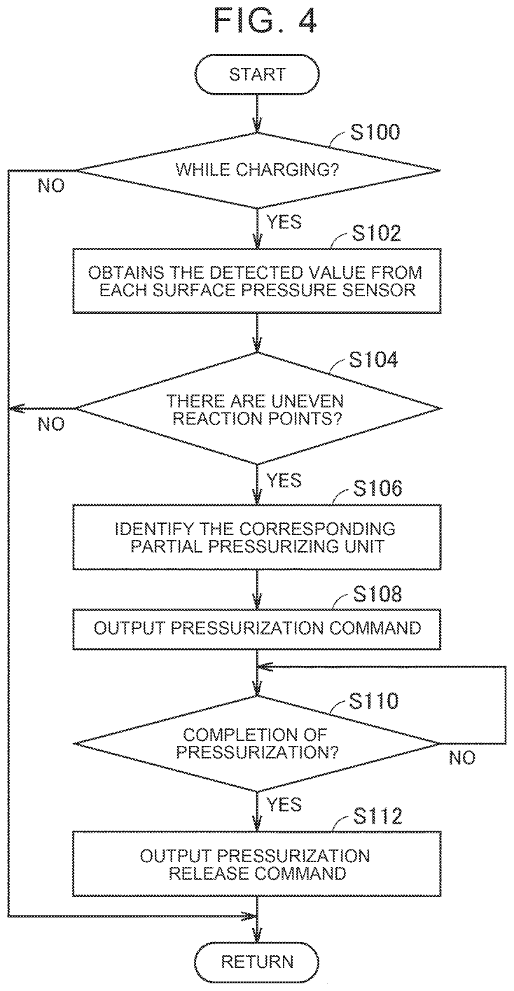

Hereinafter, an example of a process executed in the control device 100 will be described with reference to FIG. 4. FIG. 4 is a flowchart illustrating an example of processing executed by the control device 100. The series of processes shown in this flowchart is repeatedly executed by the control device 100 at predetermined intervals.

In step (hereinafter, step is referred to as S) 100, the control device 100 determines whether or not the battery pack 1 is being charged. For example, when a charging current is detected in the battery pack 1 by using a current sensor (not shown) or the like, the control device 100 may determine that the battery pack 1 is charging. When it is determined that the battery pack 1 is being charged (YES in S100), the process proceeds to S102.

In S102, the control device 100 acquires a detected value from each of the surface pressure sensors 110a to 110f. The process is then transferred to a S104.

In S104, the control device 100 determines whether or not there is any uneven response location. Specifically, the control device 100 determines that there is a reaction unevenness portion when there is a portion of the plurality of detection points where the surface pressure is higher than the other portions. The control device 100 calculates, for example, an average value of the surface pressures at a plurality of detection points. When there is a detection point higher than a value obtained by adding a predetermined value to the calculated average value among the detection values of the surface pressure at the plurality of detection points, the control device 100 determines that there is a reaction unevenness portion. If it is determined that there is an uneven part to be reacted (YES in S104), the process proceeds to S106.

In S106, the control device 100 identifies the corresponding partial pressurizing unit. The control device specifies the first partial pressurizing unit and the second partial pressurizing unit, which are positional relationships between the detection points identified as the reaction unevenness portions, as corresponding partial pressurizing units. For example, the control device 100 may store in advance a map or the like indicating the relationship between the coordinates of the detection point and the partial pressurizing unit, and may specify the corresponding partial pressurizing unit from the coordinates of the detection point corresponding to the reaction unevenness location and the map or the like. The process is then transferred to a S108.

In S108, the control device 100 outputs a pressurization command. The control device 100 sets the specified partial pressurizing unit as a control target. Then, the control device 100 outputs a pressurization command to the set control target. For example, the control device 100 may generate the pressurization command such that the constraint pressure increases by a predetermined value. Alternatively, the control device 100 may generate the pressurization command such that the constrained pressure increases by an amount corresponding to the difference between the detection value of the surface pressure at the detection point and the average value of the detection values at the respective detection points. The process is then transferred to a S110.

In S110, the control device 100 determines whether or not the pressurization is completed. For example, the control device 100 determines that the pressurization has been completed when a predetermined time has elapsed since the start of the pressurization. The process is then transferred to a S112.

In S112, the control device 100 outputs a pressurization release command. The control device 100 outputs a pressurization release command to a control target set so that pressurization by the partial pressurizing unit is stopped. The process is then terminated.

The operation of the control device 100 of the battery pack 1 according to the present embodiment based on the above-described structure and flowchart will be described.

For example, it is assumed that the battery pack 1 mounted on the vehicle is charged using an external power source or the like. Further, for example, it is assumed that the reaction unevenness occurs at a position corresponding to the first partial pressurizing unit 50a and the second partial pressurizing unit 60a in the all-solid-state battery 10b among the all-solid-state batteries 10a to 10g constituting the stack 20.

When it is determined that the battery pack 1 is being charged (YES in S100), the control device 100 acquires a detected value from each of the surface pressure sensors 110a to 110f (S102). The mean value of the surface pressure at each of the plurality of detection points is calculated using the acquired detection value of the surface pressure sensors 110a to 110f. When it is determined that the detected value of the surface pressure is larger than the value obtained by adding a predetermined value to the mean value at the detection point in the surface pressure sensor 110a among the plurality of detection points, it is determined that there is a reaction-uneven portion (YES in S104). Then, the partial pressurizing unit corresponding to the uneven part is specified (S106).

The first partial pressurizing unit 50a and the second partial pressurizing unit 60a are specified as partial pressurizing units corresponding to the reaction uneven portions from the coordinates of the surface pressure sensor 110a determined to have the reaction uneven portions in the surface pressure sensor 110a.

Then, the first partial pressurizing unit 50a and the second partial pressurizing unit 60a is a specified partial pressurizing unit is set as a control target. Then, a pressurization command is outputted to the set control target (S108).

In accordance with the pressurization command, the actuator in each of the first partial pressurizing unit 50a and the second partial pressurizing unit 60a is driven so that the first partial pressurizing unit 50a pressurizes the contact surface with the stack 20, and the second partial pressurizing unit 60a pressurizes the contact surface with the stack 20, whereby the restraint pressure at the uneven reaction portion of the stack 20 is locally increased. As a result, the adhesion between the solid electrolyte layer and the positive electrode layer or the negative electrode layer increases, and the resistance decreases, thereby eliminating the occurrence of reaction unevenness.

Pressurization is completed after a predetermined period (NO at S110). Then, when the pressurization release command is outputted (S112), the first partial pressurizing unit 50a and the second partial pressurizing unit 60a return to the pre-pressurization condition.

As described above, according to the battery pack 1 of the present embodiment, by using 110f from the surface pressure sensor 110a, the distribution of the in-plane pressure between the all-solid-state batteries 10a and 10f is detected. Therefore, by detecting a portion where a local pressure increase occurs, it is possible to accurately detect a portion where reaction unevenness occurs. Therefore, it is possible to provide a battery pack that appropriately detects reaction unevenness in an all-solid-state battery.

Further, by pressurizing a portion of the contact surface to increase the restraining pressure at the location where the reaction unevenness occurs, the adhesion of the constituent members at the location where the reaction unevenness occurs in the stack 20 is improved. Then, the reaction unevenness can be eliminated. In addition, it is possible to suppress an unnecessary restraining pressure from acting on a portion other than the generating portion.

When a plurality of portions having reaction unevenness are detected, a partial pressurizing unit corresponding to each portion having reaction unevenness is set as a control target. Then, a pressurization command is output to each set control target.

Modifications will now be described.

In the above-described embodiment, a case has been described as an example in which it is determined whether or not there is a reaction unevenness during charging. However, it may be determined whether or not there is a reaction unevenness during discharge.

Further, the above-described embodiment has been described as one in which the pressurization is determined to be completed when a predetermined time has elapsed since the pressurization command is output and the pressurization release command is output. However, for example, when the resistance value of the all-solid-state battery including the reaction unevenness portion becomes equal to or less than the threshold value after outputting the pressurization command, it may be determined that the pressurization is completed and the pressurization release command may be output.

Further, in the above-described embodiment, 10g from the all-solid-state battery 10a is removed by pressurizing from the first partial pressurizing unit 50a using at least one of 50j and 60j from the second partial pressurizing unit 60a. However, in order to promote the elimination of the reaction unevenness, for example, a heating control for heating 10g from the stack 20 or the all-solid-state battery 10a in which the reaction unevenness occurs in addition to the pressurization may be performed. In addition, voltage control for changing the voltage may be performed. The heating control may be, for example, control of heating 10g from the all-solid-state battery 10a using a heating device such as a heater. Further, the heating control may be, for example, a control of loosening the degree of cooling by a cooling device (not shown) provided in the battery pack 1. The heating control may be, for example, control for stopping cooling by the cooling device. The voltage control may be a control for increasing the voltage of the all-solid-state battery in which no reaction unevenness occurs during charging. The voltage control may be a control for stopping charging. In addition, the voltage control may be a control of lowering the voltage of the all-solid-state battery in which no reaction unevenness occurs during discharge. Further, the voltage control may be a control for stopping the discharge.

Further, in the above-described embodiment, each of the first partial pressurizing units 50a to 50j and the second partial pressurizing units 60a to 60j has the same area of the contacting surface with respect to the stack 20. However, each of the first partial pressurizing units 50a to 50j and the second partial pressurizing units 60a to 60j may have a contact surface having a different area or a different shape with respect to the stack 20.

For example, the plurality of partial pressurizing units may be arranged so as to be capable of pressurizing a part of the contact surface of the contact surface closer to the terminal (the positive electrode terminal and the negative electrode terminal) of 10g from the all-solid-state battery 10a among the contact surfaces with the stack 20. Alternatively, the plurality of partial pressurizing units may be concentrated on the side closer to the terminal.

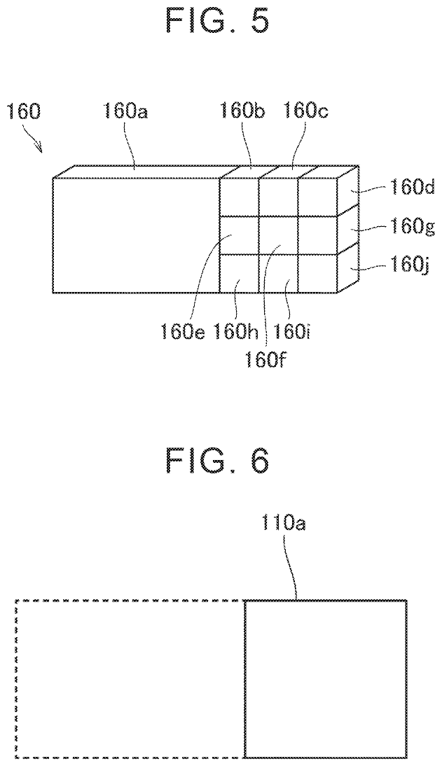

FIG. 5 is a diagram illustrating an example of the configuration of the second pressurizing unit 160 according to the modification. In FIG. 5, for convenience of explanation, the display of the stack 20 and the first pressurizing unit of the battery pack 1 is omitted, and only the second pressurizing unit 160 is displayed.

As shown in FIG. 5, the second pressurizing unit 160 includes second partial pressurizing units 160a, 160b, 160c, 160d, 160c, 160f, 160g, 160h, 160i, 160j (hereinafter, referred to as the second partial pressurizing units 160a to 160j).

The second partial pressurizing unit 160a has a rectangular contact surface with the stack 20, and has a contact surface having the largest contact surface area with the stack 20 as compared with 160j from the second partial pressurizing unit 160b. On the other hand, the contacting surface with the stack 20 of each of the second partial pressurizing units 160b to 160j has a rectangular shape and has substantially the same area.

The first pressurizing unit has a plurality of first partial pressurizing units having the same shape as the second pressurizing unit 160. The plurality of first partial pressurizing units is disposed at positions facing 160j from the second partial pressurizing unit 160a.

In this way, the restraining pressure can be partially increased with respect to a region close to the terminal, in which reaction unevenness is likely to occur in the all-solid-state battery. Therefore, the adhesiveness of the constituent member in the region close to the terminal can be improved. In addition, it is possible to suppress an unnecessary restraining pressure from acting on a portion other than the generating portion. Note that the second partial pressurizing unit 160a and the corresponding first partial pressurizing unit may be configured by omitting a mechanism that enables pressurization. In this way, it is possible to dispose the partial pressurizing unit so that a part of the contact surface closer to the terminal can be pressurized.

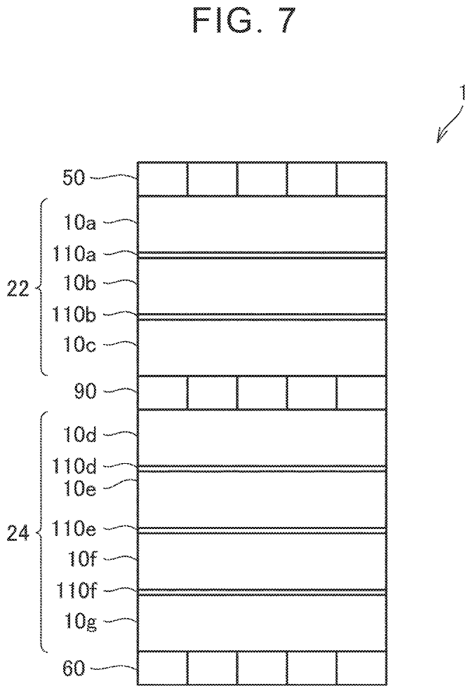

In this case, the shape of the sheet including the detection point of the surface pressure sensor may be not a shape covering the surface of the all-solid-state battery in the stacking direction, but a shape covering the region of the portion where the stack 20 and the partial pressurizing unit come into contact with each other. FIG. 6 is a diagram illustrating an example of a configuration of a surface pressure sensor according to a modification. By arranging the partial pressurizing unit in the region close to the terminal and having a shape covering the contact surface between the partial pressurizing unit and the stack 20 as shown by the solid line in FIG. 6, it is possible to reduce the shape of the sheet including the detection point of the surface contact sensor as compared with the case of covering the entire surface in the stacking direction of the all-solid-state battery including the broken line in FIG. 6.

As described above, by arranging 110f from the surface pressure sensor 110a so as to detect the distribution of the in-plane pressure between the all-solid-state batteries 10a and 10g and on the end portion side close to each terminal of 10g from the all-solid-state battery 10a in the surface, the distribution of the in-plane pressure on the end portion side close to the terminal where the reaction unevenness is likely to occur is detected. In addition, it is possible to accurately detect a portion where reaction unevenness occurs while suppressing an increase in cost.

Further, in the above-described embodiment, a configuration has been described as an example in which the restraining pressure is applied to the entire stack 20 with respect to the stacking direction of the stack 20 by providing the stack 20 so as to be sandwiched between the first pressurizing unit 50 and the second pressurizing unit 60. However, the present disclosure is not particularly limited to such a configuration.

For example, in addition to the first pressurizing unit 50 and the second pressurizing unit 60, a third pressurizing unit may be included that partially increases the restraining pressure in a section including a generation region among a plurality of sections obtained by dividing the stack 20 in the longitudinal direction.

FIG. 7 is a diagram illustrating an example of a configuration of a battery pack 1 according to a modification. As shown in FIG. 7, the battery pack 1 includes a third pressurizing unit 90 in place of the surface pressure sensor 110c in the configuration described with reference to FIG. 1. The third pressurizing unit 90 is provided so as to sandwich the first stack 22 including the three all-solid-state batteries 10a to 10c with the first pressurizing unit 50. Further, the third pressurizing unit 90 is provided so as to sandwich the second stack 24 containing the remaining all-solid-state batteries 10d to 10g with the second pressurizing unit 60. The third pressurizing unit 90 includes a plurality of third partial pressurizing units (not shown). The third pressurizing unit is configured to be pressurizable to both the first stack 22 and the second stack 24. Each of the plurality of third partial pressurizing units operates in response to a control signal from the control device 100, and is provided at a position corresponding to each of the partial pressurizing unit of the first pressurizing unit 50 and the pressurizing unit of the second pressurizing unit 60. The third pressurizing unit 90 may be provided to be fastened to, for example, a pedestal or the like that fixes the battery pack 1. In addition, the position of the third pressurizing unit 90 may be limited by fixing the first pressurizing unit 50 and the second pressurizing unit 60 in the same manner as the adjacent first stack 22 and the second stack 24.

The control device 100 specifies a portion where unevenness is generated by using the detection result at a plurality of detection points using the surface pressure sensors 110a, 110b, 110d, 110c, 110f. Then, the control device 100 operates the partial pressurizing unit corresponding to the specified portion.

For example, when it is determined that there is a reaction unevenness portion in the first stack 22, the control device 100 operates the partial pressurizing unit corresponding to the generated portion in the first pressurizing unit 50 and the third pressurizing unit 90 to partially increase the restraining pressure.

Further, for example, when it is determined that there is a reaction unevenness portion in the second stack 24, the control device 100 operates the partial pressurizing unit corresponding to the generated portion in the third pressurizing unit 90 and the second pressurizing unit 60 to partially increase the restraining pressure.

In this way, it is possible to concentrate the portion where the reaction unevenness occurs and to increase the restraining pressure. Therefore, it is possible to improve the adhesion in the region where the reaction unevenness is generated, and it is possible to suppress an unnecessary restraining pressure from acting on the other portion.

All or some of the above-mentioned modified examples may be combined for implementation.

It should be considered that the embodiments disclosed above are for illustrative purposes only and are not limitative of the disclosure in any aspect. The scope of the disclosure is indicated by the appended claims rather than by the foregoing description. It is intended that the scope of the disclosure include all modifications within the meaning and range of equivalency of the claims.

What is claimed is:

1. A battery pack comprising:
a first all-solid-state battery;
a second all-solid-state battery;
a surface pressure sensor provided between the first all-solid-state battery and the second all-solid-state battery in a bound state and configured to detect a distribution of an in-plane pressure between the first all-solid-state battery and the second all-solid-state battery; and
a control device configured to detect, by using a detection result from the surface pressure sensor, a portion where a local pressure increase occurs between the first all-solid-state battery and the second all-solid-state battery as a portion where reaction unevenness occurs.

2. The battery pack according to claim 1, wherein the first all-solid-state battery and the second all-solid-state battery have a characteristic that a thickness in an arrangement direction of the first all-solid-state battery and the second all-solid-state battery increases compared with a thickness in an initial state due to the reaction unevenness that occurs during charging or discharging of the battery pack.

3. The battery pack according to claim 1, wherein the surface pressure sensor is configured to detect the distribution of the in-plane pressure between the first all-solid-state battery and the second all-solid-state battery on an end side close to a first terminal of the first all-solid-state battery and a second terminal of the second all-solid-state battery in a plane.
